(19) United States
(12) Patent Application Publication
(10) Pub. No.: US 2015/0282344 A1
(43) Pub. Date: Oct. 1, 2015

(54) CARRIER DEVICE FOR TWO OR MORE ARTICLES

(71) Applicant: Oxti Corporation, Taipei (TW)

(72) Inventor: Chih Feng HO, Taipei (TW)

(73) Assignee: Oxti Corporation, Taipei (TW)

(21) Appl. No.: 14/225,500

(22) Filed: Mar. 26, 2014

(51) Int. Cl. H05K 5/02; F16M 11/08; F16B 2/12; F16M 11/04; F16B 2/14

(52) U.S. Cl. CPC H05K 5/0204; F16M 11/045; F16B 2/14; F16B 2/12; F16M 11/08

(57) ABSTRACT

A carrier device includes a mounting seat supported on a supporting base for supporting an object, a lever attached to the mounting seat, and a mount fixture attached to the lever for supporting an article and for allowing the user to easily view or operate the object and the article simultaneously. The mounting seat includes a channel for slidably engaging with the lever. The mounting seat includes a lock mechanism engaged with the lever for locking the lever to the mounting seat at a selected position. The mount fixture includes a frame and a sliding member adjustably secured together with a fastener for engaging with the article and for retaining the article to the frame.

### BACKGROUND OF THE INVENTION

1. Field of the Invention

The present invention relates to a carrier device for supporting various objects, such as monitors, keyboards, displayers, antenna members or the like, and more particularly to a carrier device including an improved structure for stably supporting two or more objects or the like at the selected or suitable positions for allowing the user to easily view or operate two or more objects or monitors or keyboards or antenna members or displayers simultaneously.

2. Description of the Prior Art

Typical carrier devices for supporting such as monitors or antenna members or displayers or keyboards comprise a mounting seat for attaching or coupling to the monitors or the antenna members or the displayers or the keyboards, and a movable seat and an engaging plate pivotally coupling the mounting seat to a carrier plate for pivotally coupling and supporting the monitors or the antenna members or the displayers or the keyboards to the carrier plate and for adjustably supporting the monitors or the antenna members or the displayers or the keyboards at the selected or suitable or predetermined angular positions relative to the carrier plate.

For example, U.S. Pat. No. 5,901,933 to Lin, U.S. Pat. No. 5,941,497 to Inoue et al., U.S. Pat. No. 6,021,985 to Hahn, U.S. Pat. No. 6,027,090 to Liu, and U.S. Pat. No. 7,413,152 to Chen disclose several of the typical carrier devices each comprising a movable seat and an engaging plate disposed parallel to each other and pivotally coupled between a carrier plate and a mounting seat, in which the mounting seat may be used for supporting the monitors or antenna members or keyboards, and thus for allowing the monitors or antenna members or keyboards and the carrier plate to be adjustably supported at the selected or suitable or predetermined angular position relative to the carrier plate.

However, the mounting seat may be used for supporting a single monitor or antenna member or keyboard or article or the like and may not be used to support two or more monitors, keyboards, displayers, antenna members or the like, and may have to use one of the user's hand to hold and support the other monitor, keyboard, displayer, antenna member or the like, and thus may not suitably operate the articles.

The present invention has arisen to mitigate and/or obviate the afore-described disadvantages of the conventional carrier devices for supporting the monitors or the displayers or the keyboards or the like.

### SUMMARY OF THE INVENTION

The primary objective of the present invention is to provide a carrier device including an improved structure for stably supporting two or more objects or the like at the selected or suitable positions for allowing the user to easily view or seen or operate two or more objects or monitors or keyboards or antenna members or displayers simultaneously.

In accordance with one aspect of the invention, there is provided a carrier device comprising a supporting base, a mounting seat supported on the supporting base for supporting an object, a lever slidably or adjustably attached to the mounting seat, and a mount fixture attached to the lever for supporting an article and for allowing the user to easily view or operate the object and the article simultaneously.

The mounting seat is pivotally or rotatably supported on the supporting base with a rod or post. The mounting seat includes a channel formed therein for slidably receiving and engaging with the lever and for allowing the lever to be slid or moved or adjusted along the channel of the mounting seat to the selected or required or suitable positions.

The mounting seat includes a lock mechanism engaged with the lever for locking the lever to the mounting seat at the selected position. The lock mechanism includes two latches each pivotally attached to the mounting seat with a pivot axle, and the latches each include a cam member provided thereon for selectively engaging with the lever and for selectively retaining or locking the lever to the mounting seat at the selected position.

The latches each include a pinion provided thereon and pivotally attached to the mounting seat with the pivot axle, and the pinions of the latches are meshed with each other. The latches each include a handle extended therefrom for actuating the cam members of the latches to engage with the lever and to be disengaged from the lever.

The mount fixture includes a frame and a sliding member slidably and adjustably attached or mounted or secured or coupled together for engaging with the article and for retaining the article to the frame. The frame and the sliding member each include a limb for engaging with the article.

The frame includes a groove formed therein, and a fastener is slidably received and engaged in the groove of the frame and secured to the sliding member for slidably and adjustably coupling the frame and the sliding member together and for allowing the frame and the sliding member to be slid or moved or adjusted relative to each other.

The mount fixture includes a coupler engaged with the fastener and the frame for allowing the coupler and the frame and the sliding member to be adjustably secured together with the fastener. The mount fixture includes a bracket pivotally coupled to the coupler with a joint, and the lever is pivotally coupled to the bracket with a hinge.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a partial perspective view of a carrier device in accordance with the present invention for supporting two or more monitors or displayers or antenna members or keyboards or articles or the like;

FIG. 2 is a partial exploded view of the carrier device;

FIG. 3 is a partial rear plan schematic view illustrating the operation of the carrier device; and

FIG. 4 is another partial perspective view illustrating the operation of the carrier device.

### DETAILED DESCRIPTION OF THE PREFERRED EMBODIMENT

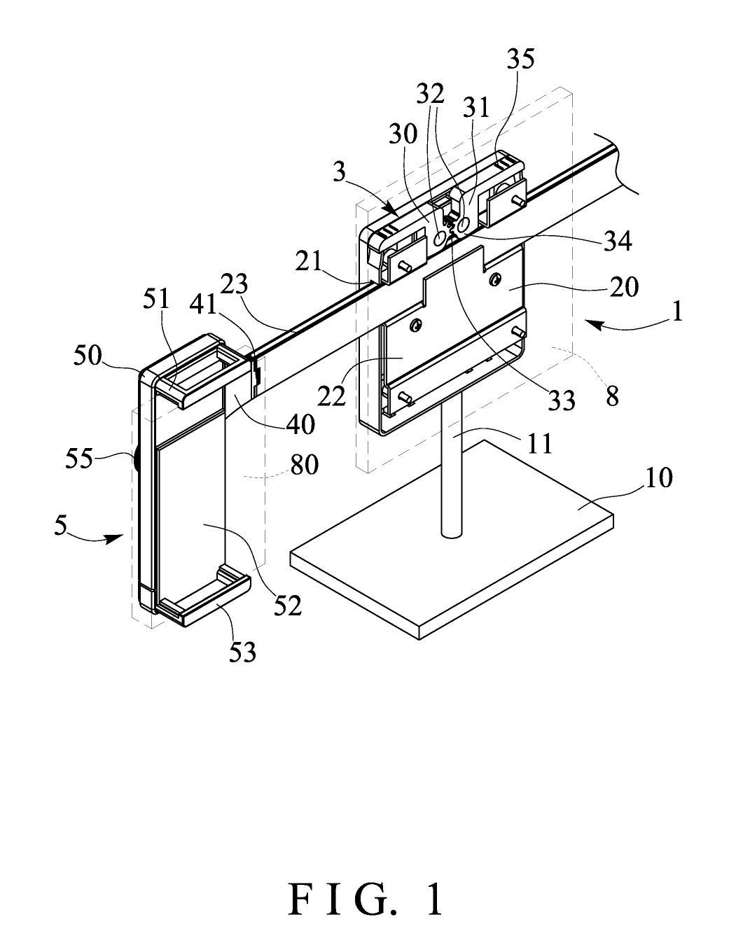

Referring to the drawings, and initially to FIG. 1, a carrier device 1 in accordance with the present invention is provided for supporting various objects 8, 80, such as two or more displayers, monitors 8, antenna members, articles, portable or mobile phones 80, keyboards, or the like, and for supporting the monitors 8 or the displayers or the keyboards or the articles or the antenna members or the mobile phones 80 or the like at the selected or suitable or predetermined position relative to the supporting table (not shown) or the like, and comprises a supporting base 10 for being disposed or supported on the supporting table (not shown).

A mounting seat 20 is to be rotatably or pivotally coupled to and supported on the supporting base 10 with a rod or pole or post 11 for coupling or attaching or supporting or securing one of the objects or displayers or monitors 8 to the supporting base 10. The mounting seat 20 includes a groove or channel 21 formed therein, such as formed in the back or rear portion 22 of the mounting seat 20 for slidably receiving or engaging with a bar or beam or lever 23, and includes a catch or latch or lock mechanism 3 attached or mounted or engaged onto the mounting seat 20 for selectively engaging with the lever 23 and for catching or latching or locking the lever 23 to the mounting seat 20 at the selected or suitable positions.

For example, the lock mechanism 3 includes one or more (such as two) mount linkages or fixtures or catches or latches 30, 31 each pivotally or rotatably attached or mounted or secured to the mounting seat 20 with a pivot axle 32, and each having a number of teeth or a gear or pinion 33 formed or provided thereon, and the pinions 33 of the latches 30, 31 are meshed or engaged with each other, and the latches 30, 31 each include a cam member 34 formed or provided thereon for selectively contacting or engaging with the lever 23 and for catching or latching or locking the lever 23 to the mounting seat 20 at the selected or suitable positions, each include a knob or hand grip or handle 35 extended therefrom for actuating or operating the cam members 34 of the latches 30, 31 to engage with or to be disengaged from the lever 23.

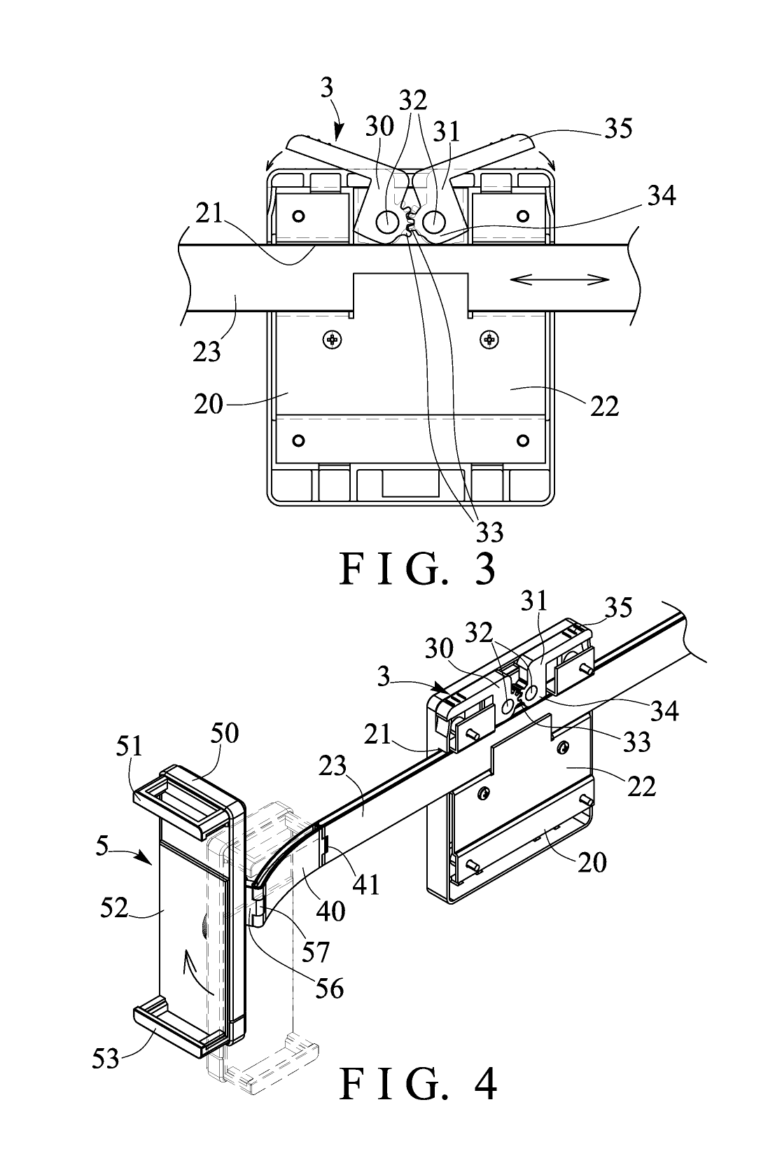

In operation, as shown in FIGS. 1 and 4, when the cam members 34 of the latches 30, 31 are disengaged from the lever 23, the lever 23 may be slid or moved or adjusted along the channel 21 of the mounting seat 20 to the selected or required or suitable positions, and the handles 35 may then pivot or rotate the latches 30, 31 relative to the mounting seat 20 to engage the cam members 34 with the lever 23 (FIG. 3) and to solidly and stably catch or latch or lock the lever 23 to the mounting seat 20 at the selected or required or suitable positions.

One or more frames or extensions or brackets 40 may further be provided and pivotally or rotatably attached or mounted or coupled to the lever 23 with pivot axles or hinges or joints 41 and for allowing the brackets 40 to be pivoted or rotated relative to the lever 23 to the required or selected or suitable positions, and for mounting or supporting a mount fixture 5 which may be used for supporting the other objects or articles 8, 80, such as the displayers, monitors 8, antenna members, portable or mobile phones 80, keyboards, or the like, and thus for allowing the two or more objects or articles 8, 80 to be easily viewed or seen by the user simultaneously.

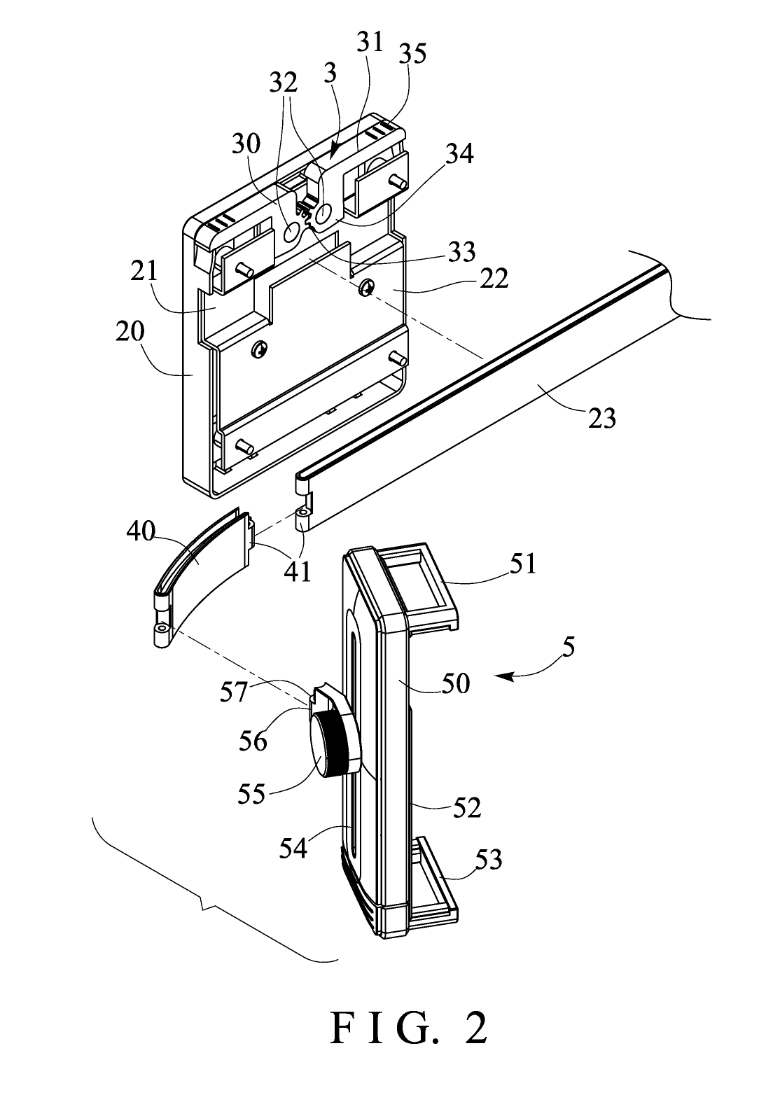

For example, the mount fixture 5 includes a frame 50 having a finger or limb 51 for engaging with the article 80, and a sliding member 52 slidably attached or mounted or secured or engaged onto the frame 50 and also having a finger or limb 53 for engaging with the article 80 and for clamping or anchoring or retaining or positioning the article 80 to the frame 50 and the sliding member 52 of the mount fixture 5, and the frame 50 includes an oblong hole or groove 54 formed therein (FIG. 2) for slidably receiving or engaging with a latch or lock or fastener 55 which is attached or mounted or secured or engaged with the sliding member 52 for slidably and adjustably coupling the frame 50 and the sliding member 52 together.

The mount fixture 5 further includes an arm or coupler 56 engaged with the fastener 55 and the frame 50 for allowing the coupler 56 and the frame 50 and the sliding member 52 to be selectively secured or locked or coupled together with the fastener 55, and the coupler 56 may be pivotally or rotatably attached or mounted or coupled to the bracket 40, or directly coupled to the lever 23 with pivot axles or hinges or joints 57 and for allowing the coupler 56 and the frame 50 and the sliding member 52 of the mount fixture 5 to be pivoted or rotated relative to the bracket 40 and/or the lever 23 to the required or selected or suitable positions, and for allowing the two or more objects or articles 8, 80 to be easily viewed or seen by the user simultaneously.

In operation, as shown in FIG. 1, an article or object 8 may be held or supported on the mounting seat 20, and the other object or article 80 may be held or supported on the frame 50 and the sliding member 52 of the mount fixture 5, and the mount fixture 5 may be pivoted or rotated relative to the bracket 40 and/or the lever 23 to the required or selected or suitable positions for allowing the two or more objects or articles 8, 80 to be easily viewed or seen by the user simultaneously. For example, the object 8 may be selected from a portable computer or personal computer or displayer or monitor 8 or the like, and the article 80 may be selected from an intelligent pad or intelligent phone or portable or mobile phone 80 and may be electrically connected or coupled to the object 8 wirelessly or with cables (not shown), for allowing the screens (not shown) of the objects or articles 8, 80 to be easily viewed or seen by the user simultaneously.

Accordingly, the carrier device includes an improved structure for stably supporting two or more objects or the like at the selected or suitable positions for allowing the user to easily view or operate two or more objects or monitors or keyboards or antenna members or displayers simultaneously.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A carrier device comprising:
a supporting base,
a mounting seat supported on said supporting base for supporting an object,
a lever attached to said mounting seat, and
a mount fixture attached to said lever for supporting an article.

2. The carrier device as claimed in claim 1, wherein said mounting seat is supported on said supporting base with a post.

3. The carrier device as claimed in claim 1, wherein said mounting seat includes a channel formed therein for slidably receiving and engaging with said lever.

4. The carrier device as claimed in claim 1, wherein said mounting seat includes a lock mechanism engaged with said lever for locking said lever to said mounting seat at a selected position.

5. The carrier device as claimed in claim 4, wherein said lock mechanism includes two latches each pivotally attached to said mounting seat with a pivot axle, and said latches each include a cam member provided thereon for selectively engaging with said lever.

6. The carrier device as claimed in claim 5, wherein said latches each include a pinion provided thereon, and said pinions of said latches are meshed with each other.

7. The carrier device as claimed in claim 5, wherein said latches each include a handle extended therefrom for actuating said cam members of said latches to engage with and to be disengaged from said lever.

8. The carrier device as claimed in claim 1, wherein said mount fixture includes a frame and a sliding member for engaging with the article and for retaining the article to said frame.

9. The carrier device as claimed in claim 8, wherein said frame and said sliding member each include a limb for engaging with the article.

10. The carrier device as claimed in claim 8, wherein said frame includes a groove formed therein, and a fastener slidably received and engaged in said groove of said frame and secured to said sliding member for slidably and adjustably coupling said frame and said sliding member together.

11. The carrier device as claimed in claim 10, wherein said mount fixture includes a coupler engaged with said fastener and said frame for allowing said coupler and said frame and said sliding member to be secured together with said fastener.

12. The carrier device as claimed in claim 11, wherein said mount fixture includes a bracket pivotally coupled to said coupler with a joint, and said lever is pivotally coupled to said bracket with a hinge.
